(19) United States
(12) Patent Application Publication
(10) Pub. No.: US 2013/0255765 A1
(43) Pub. Date: Oct. 3, 2013

(54) DOPED AI PASTE FOR LOCAL ALLOYED JUNCTION FORMATION WITH LOW CONTACT RESISTANCE

(71) Applicant: James M. GEE, Albuquerque, NM (US)

(72) Inventor: James M. GEE, Albuquerque, NM (US)

(73) Assignee: Applied Materials, Inc., Santa Clara, CA (US)

(21) Appl. No.: 13/788,208

(22) Filed: Mar. 7, 2013

Related U.S. Application Data
(60) Provisional application No. 61/618,544, filed on Mar. 30, 2012.

(51) Int. Cl. H01L 31/18; H01L 31/032

(52) U.S. Cl. CPC H01L 31/18; H01L 31/032
USPC 136/256; 438/93

(57) ABSTRACT

Embodiments of the invention generally relate to solar cells having reduced carrier recombination and methods of forming the same. The solar cells have eutectic local contacts and passivation layers which reduce recombination by facilitating formation of a back surface field (BSF). A patterned aluminum back contact doped with a Group III element is disposed on the passivation layer for removing current form the solar cell. The methods of forming the solar cells include depositing a passivation layer including aluminum oxide and silicon nitride on a back surface of a solar cell, and then forming openings through the passivation layer. An aluminum back contact doped with a Group III element is disposed on the passivation layer in a pattern covering the holes, and thermally processed to form a silicon-aluminum eutectic within the openings.

### CROSS-REFERENCE TO RELATED APPLICATIONS

This application claims benefit of U.S. Provisional Patent Application Ser. No. 61/618,544, filed Mar. 30, 2012, entitled “DOPED Al PASTE FOR LOCAL ALLOYED JUNCTION FORMATION WITH LOW CONTACT RESISTANCE”, which is herein incorporated by reference.

### BACKGROUND OF THE INVENTION

1. Field of the Invention

Embodiments of the invention generally relate to solar cells having reduced carrier recombination, and thus higher efficiency, and methods of forming the same.

2. Description of the Related Art

Solar cells generate energy via the photovoltaic effect which is enabled by exposing the solar cells to radiation, such as sunlight. Illumination of a solar cell with radiation creates an electric current as excited electrons and the holes move in different directions through the radiated cell. The electric current may be extracted from the solar cell and used as energy.

The efficiency of solar cells is directly related to the ability of a cell to collect charges generated from absorbed photons in the various layers. When electrons and holes recombine, the incident solar energy is re-emitted as heat or light, thereby lowering the conversion efficiency of the solar cells. Recombination may occur in the bulk silicon of a substrate, which is a function of the number of defects in the bulk silicon, or on the front or rear surface of a substrate, which is a function of how many dangling bonds, i.e., unterminated chemical bonds (manifesting as trap sites), are on the substrate surface. Dangling bonds are typically found on the surface of the substrate because the silicon lattice of the substrate ends at the front or rear surface. These dangling bonds act as defect traps and therefore are sites for recombination of electron-hole pairs. Good surface passivation layers can help to reduce the number of recombination locations and improve open circuit voltage and photo current produced by solar cells.

Recombination losses may be reduced by disposing a passivation layer on a back surface of solar cell devices. The passivation layer may be a dielectric layer which provides good interface properties that reduce the recombination of the electrons and holes. A dielectric layer also improve the optical reflectance of the rear surface, which improves light absorption and thus the photocurrent in the solar cell. In conventional practice, the passivation layer may be etched, drilled and/or patterned to form contact openings (e.g., back contact through-holes) that allow portions of a back contact metal layer to extend through the passivation layer to form electrical contact sites within the active regions of the device (i.e., bulk silicon of a substrate). In cases where aluminum is used as the back contact metal layer, the aluminum is alloyed with the silicon inside the contact openings during a metallization firing process, thereby forming a thin Al-doped junction region, which is commonly known as a back-surface field (BSF). The BSF formed at contact sites in a solar cell substrate is advantageous since they create an electric field with the substrate that “reflects” the minority carriers away from the contact sites, which can increase the likelihood of the current being collected and effectively reduce the back surface recombination velocity, thus improving a solar cell's short-circuit current and reducing electron-hole recombination losses. The BSF also provides for lower electrical resistance at the contact, thereby reducing the contact resistance.

However, getting good contact inside the contact openings with the alloyed Al has been problematic. One of the reasons is the void formation at the electrical contact site after the metallization firing process. An explanation for this void phenomenon is conceptually shown in FIG. 1. During the heating ramp of the metallization firing process, the silicon at the electrical contact site 103 rapidly dissolves into the melt and transports away via diffusion into the aluminum back contact layer 106, as indicated by arrows “D1”. At the same time, the aluminum in the aluminum back contact layer 106 also dissolves and migrates into the contact site where the silicon is dissolved (indicated by arrows “D2”), at a velocity slower than that of the silicon due to a slower solubility of aluminum in silicon or silicon liquid alloy than that of silicon in aluminum. Therefore, a higher volume of silicon atoms diffuse into the aluminum back contact layer 106 than aluminum atoms in the silicon or silicon liquid alloy. During the subsequent cooling ramp of the metallization firing process, the dissolved silicon does not have enough time to diffuse back to where it was dissolved (since the cooling ramp is typically much faster than the heating ramp), resulting in formation of voids 102 within the bulk silicon substrate 100. The voids 102 are also formed partly due to the fact that aluminum has not completely diffused into and filled the voids 102. The formation of voids 102 at the electrical contact sites causes contact resistance to increase, which is undesirable particularly in local BSF application because the Al-doped BSF 104 only covers a small percentage (e.g., 1%) of the back surface of the solar cell.

Therefore, there exists a need for an improved method of manufacturing solar cell devices that has a reduced contact resistance inside the contact openings.

### SUMMARY OF THE INVENTION

Embodiments of the invention generally relate to solar cells having reduced carrier recombination and methods of forming the same. The solar cells have eutectic local contacts and passivation layers which reduce recombination by facilitating formation of a back surface field (BSF). A patterned aluminum back contact is disposed on the passivation layer for removing current form the solar cell. The patterned back contact reduces the cost-per-watt of the solar cell by using less material than a full-surface back contact. In various embodiments, the method of forming the solar cells includes depositing a passivation layer including aluminum oxide and silicon nitride on a back surface of a solar cell, and then forming contact openings through the passivation layer. A patterned, boron-doped aluminum back contact is disposed on the passivation layer covering the holes. The substrate and the back contact deposited thereon are then thermally processed to form a silicon-aluminum eutectic and a heavily boron-doped region (i.e., back-surface field (BSF)) within the contact openings.

In one embodiment, a solar cell device is disclosed. The solar cell device generally includes a substrate, a passivation layer disposed on a non-light-receiving surface of the substrate, and the passivation layer having a plurality of openings formed therethrough. The passivation layer comprises a first sub-layer of aluminum oxide, and a second sub-layer of silicon nitride disposed on the first sub-layer of aluminum oxide. A back contact is then disposed on the passivation layer in a grid-like pattern covering the openings. The back contact comprises an aluminum doped with a Group III element. The solar cell device also includes a plurality of local contacts formed at an interface of the substrate and the back contact disposed within the openings, wherein the plurality of local contacts comprises a region heavily doped with the Group III element and a silicon-aluminum eutectic alloy formed adjacent to the heavily doped region.

In another embodiment, a method of forming a solar cell is disclosed. The method generally includes disposing a passivation layer on a non-light receiving surface of a substrate. The passivation layer comprises a first sub-layer of aluminum oxide and a second sub-layer of silicon nitride disposed on the first sub-layer of aluminum oxide. A plurality of openings is then formed through the passivation layer, and an aluminum paste is disposed over the passivation layer in a grid-like pattern covering the openings. In one aspect, the aluminum paste comprises a Group III element. The substrate is then thermally processed, which includes heating the substrate and the aluminum paste disposed thereon to a temperature above a silicon-aluminum eutectic point, and allowing the substrate to cool.

In yet another embodiment, a method of forming a solar cell is disclosed. The method generally includes providing a substrate having a front surface and a back surface, wherein the back surface is generally parallel and opposite to the front surface, and the substrate has a first conductivity type. A plurality of holes are then formed in the substrate extending from the front surface to the back surface of the substrate. An emitter layer is then formed within the holes and on the front and back surfaces, the emitter layer having a second conductivity type opposite to the first conductivity type. Thereafter, an aluminum paste comprising a Group III element is disposed on the back surface of the substrate. The substrate and the aluminum paste disposed thereon are then heated to a temperature above a silicon-aluminum eutectic point to form a region heavily doped with the Group III element in the substrate.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic sectional view of a solar cell showing mass transportation of silicon and aluminum at electrical contact sites during a metallization firing process.

FIG. 2 is a schematic sectional view of a solar cell according to one embodiment of the invention.

FIG. 3 is a schematic plan view of a back surface of the solar cell shown in FIG. 2.

FIG. 4 is flow diagram illustrating a method of forming a solar cell.

FIG. 5 is a perspective view of a solar cell according to another embodiment of the invention.

FIG. 6 is flow diagram illustrating a method of forming the solar cell shown in FIG. 5.

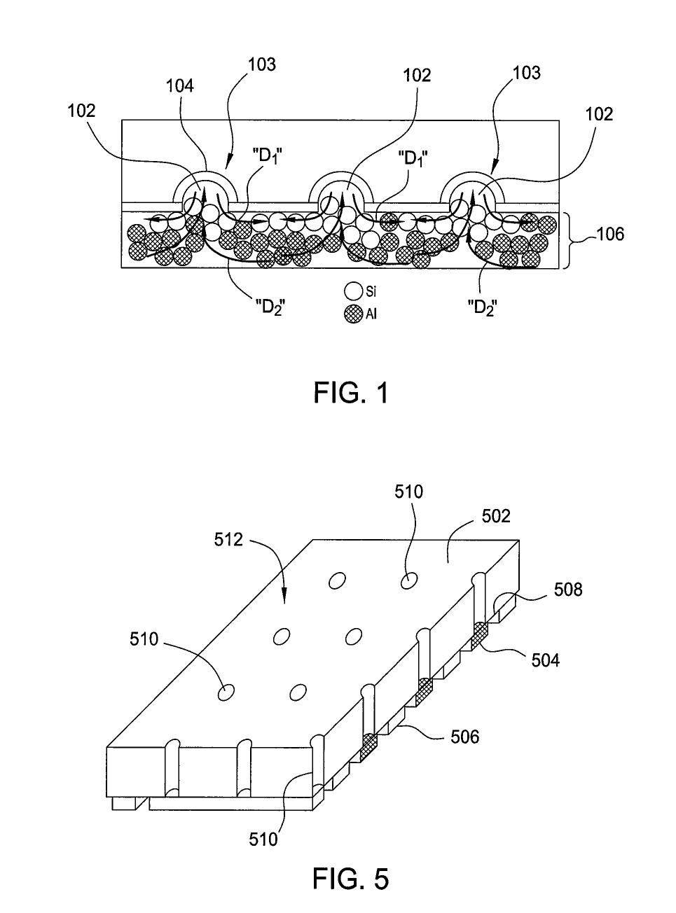

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the invention generally relate to methods for manufacturing solar cells. Particularly, embodiments of the invention provide methods of forming a more heavily doped back-surface field (BSF) by forming a metal paste doped with a Group III element on the back surface of the solar cell. The metal paste functions as a back surface contact for the solar cell and may be arranged in grid-like patterns. The grid-like patterned back surface contact reduces the cost-per-watt of the solar cell by using less material than a full-surface back contact. In one embodiment, methods of forming the solar cells include depositing a passivation layer stack including aluminum oxide (AlₓO_{y}) and silicon nitride (SiₓN_{y}) on a back surface of a silicon substrate, and then forming contact openings through the passivation layer stack. A patterned aluminum paste doped with an element, such as boron, is then disposed on the passivation layer stack over the contact openings. Thereafter, the substrate and the boron-doped aluminum paste are heated by a thermal process to a temperature above a silicon-aluminum eutectic point to form a heavily boron-doped region within the contact openings, particularly at the interface between the silicon substrate and the silicon-aluminum eutectic.

The heavily doped back-surface field (BSF) in accordance with the present invention leads to lower contact resistance between the back surface contact and the silicon substrate, thus providing high open circuit voltage to the solar cell device with improved reliability due to good adhesion at the substrate surface. The heavily doped BSF repels photo-induced electrons away from the back surface and thus reduces electron-hole recombination at the back surface of the solar cell device, thereby increasing overall cell efficiency. Methods of forming the heavily doped back-surface field in accordance with the present invention are also applicable to other types of solar cell devices using a back-contact silicon substrate prepared by emitter wrap through (EWT), metallization wrap around (MWA), or metallization wrap through (MWT) approaches.

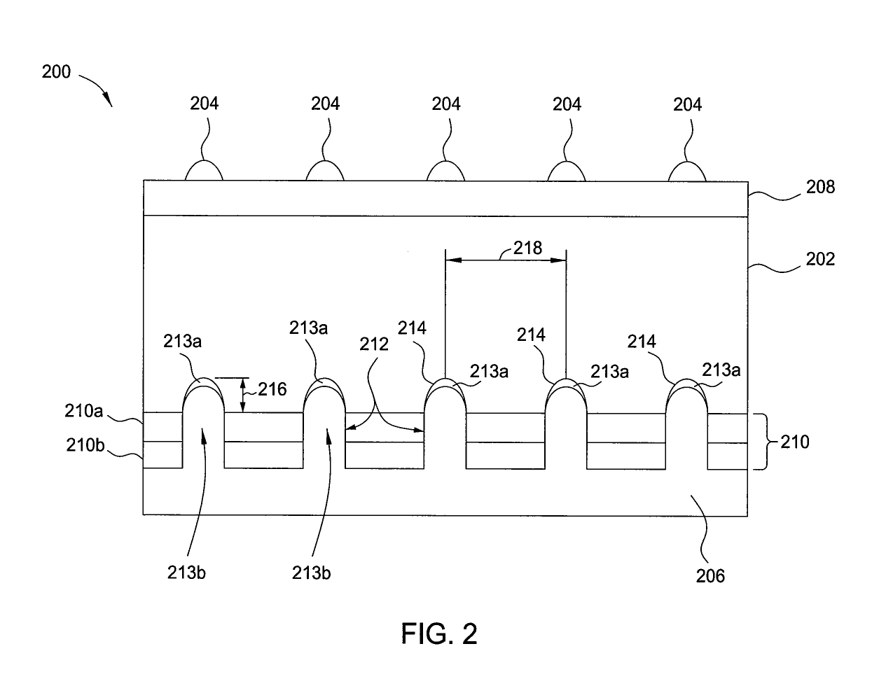

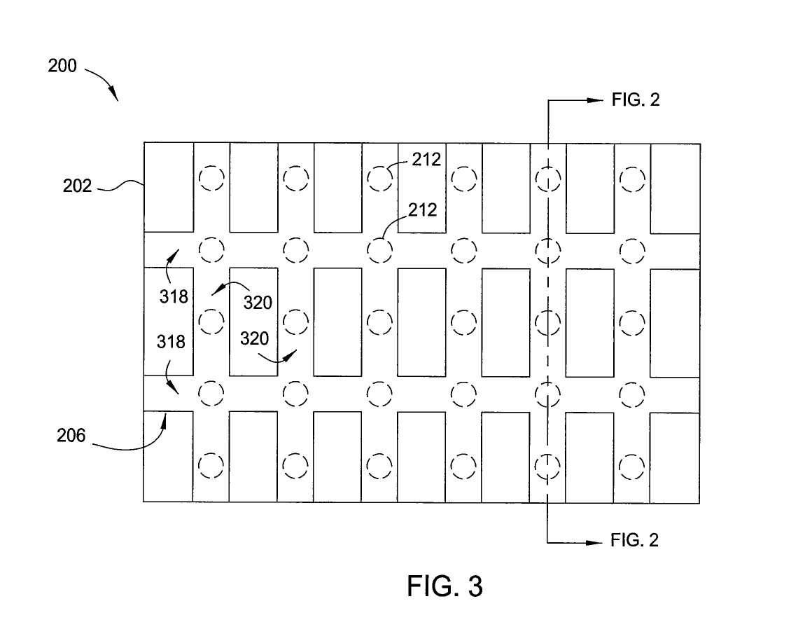

FIG. 2 is a schematic sectional view of a solar cell 200 according to one embodiment of the invention. The solar cell 200 includes a semiconductor substrate 202. The substrate 202 may be a single crystal or multicrystalline silicon substrate, silicon containing substrate, doped silicon containing substrate, or other suitable substrate. The crystalline silicon substrate 202 may be an electronic grade silicon substrate or a low lifetime, defect-rich silicon substrate, for example, an upgraded metallurgical grade (UMG) crystalline silicon substrate. The upgraded metallurgical grade (UMG) silicon is a relatively clean polysilicon raw material having a low concentration of heavy metals and other harmful impurities, for example in the parts per million range, but which may contain a high concentration of boron or phosphorus, depending on the source. In the embodiment depicted in FIG. 2, the substrate 202 is a p-type crystalline silicon (c-Si) substrate. P-type dopants used in silicon solar cell manufacturing are chemical elements, such as, boron (B), aluminum (Al) or gallium (Ga). While the embodiment depicted herein and relevant discussion thereof primarily discuss the use of a p-type c-Si substrate, this configuration is not intended to be limiting as to the scope of the invention, since an n-type c-Si substrate may also be used without deviating from the basic scope of the embodiments of the invention described herein.

The solar cell 200 generally includes a front surface contact 204 disposed on a light-receiving surface of the solar cell 200 and a back surface contact 206 disposed on the non-light-receiving surface of the solar cell 200. The front surface contact 204 and the back surface contact 206 may be arranged in grid-like patterns including one or more busbars and a plurality of fingers coupled therewith and arranged perpendicularly thereto, such as busbars 318 and fingers 320 shown in FIG. 3. The solar cell 200 also includes a doped region 208 adjacent to the front surface contact 204. The doped region 208 may be a p⁺ or n⁺ doped region, depending upon the conductive type of the substrate used. In the embodiment shown in FIG. 2, the doped region 208 comprises an n-type dopant that is disposed in the p-type substrate 202.

The solar cell 200 further includes a passivation layer 210 disposed on the back surface of the substrate. The passivation layer 210, in combination with local contacts 214 (which are formed from the back surface contact material), facilitates formation of a back-surface field (BSF) 213a in a region around the local contacts 214 which repels minority charge carriers. The minority charge carriers are repelled due to the presence of a high concentration of a p-type dopant, such as aluminum or boron, within the formed local contacts 214. The repelling of minority charge carriers reduces carrier recombination near the non-light-receiving surface of the solar cell 200.

The passivation layer 210 may be a dielectric layer providing good surface/interface properties that reduces the recombination of the electrons and holes, drives and/or diffuses electrons and charge carriers. In one embodiment, the passivation layer 210 may be fabricated from one or more dielectric materials selected from a group consisting of silicon nitride (SiₓN_{y}), silicon nitride hydride (SiₓN_{y}:H), silicon oxide, silicon oxynitride, aluminum oxide (AlₓO_{y}), a tantalum oxide, titanium oxide, or the like. In one embodiment as illustrated in FIG. 2, the passivation layer 210 includes two sub-layers, for example an aluminum oxide layer 210a and a silicon nitride layer 210b covering the aluminum oxide layer 210a. In one example, the aluminum oxide layer 210a may have a thickness between about 5 microns and about 120 nm, for example, about 20 microns to about 50 microns; the silicon nitride layer 210b may have a thickness between about 5 nm and about 200 nm, for example, about 50 microns to about 80 nm. In various examples, the total thickness of the passivation layer 210 is about 100 nm. The aluminum oxide layer 210a passivates any dangling bonds present on the back surface of the substrate 202 and has an effective fixed negative charge to improve field effect passivation. Negative fixed charge is good for passivation of p-type surfaces while positive fixed charge is good for passivation of n-type surfaces. The correct polarity provides a field to repel minority charge carriers from the surface. The silicon nitride layer 210b protects the aluminum oxide layer 210a from some materials used to form the back surface contact 206, which may adversely affect the aluminum oxide layer 210a and therefore degrade the passivation qualities of the aluminum oxide layer 210a. The silicon nitride layer 210b also prevents the aluminum oxide from reacting with subsequently deposited back surface contact material (e.g., Al) during the firing process, which is performed to create contact openings or vias in the passivation layer 210 to form electrical contact with the silicon substrate 202.

The passivation layer 110 includes a plurality of contact openings 212 formed in the passivation layer 110 to allow electrical communication between the substrate 202 and the back surface contact 206. The contact openings 212 have a diameter within a range of about 20 microns to about 200 microns, and a pitch (i.e., contact spacing 218) of about 100 microns to about 1000 microns across the back surface of the substrate 202. The contact openings can also form nearly continuous lines rather than distributed contact openings. The back contact 206 extends into the contact openings 212 and is thermally processed to form local contacts 214. The formed local contacts 214 are generally comprised of a homogeneous back-surface field (BSF) 213a and a eutectic region 213b formed from the back surface contact 206 and the silicon substrate 202. In one embodiment of the invention, a boron-doped aluminum paste is used to form the back surface contact 206. In such an embodiment, the back surface contact 206 may include a eutectic region 213b formed of an aluminum-silicon eutectic alloy and a back-surface field 213a heavily doped with boron and a small amount of aluminum. In one example, the back-surface field 213a may be doped with B to about 1E18 cm-3 to about 1E20 cm-3 and doped with Al from about 3E17 cm-3 to about 3E18 cm-3. The local contacts 114 may extend past the passivation layer 210 a distance 216, which is within a range of about 1 microns to about 30 microns. The distance 216 is generally dependent on the diameter of the contact openings 212, as well as the length of time and temperature of the heating process used to form the eutectic alloy material within the local contacts 214.

FIG. 2 describes one embodiment of a solar cell 200. However, other embodiments are also contemplated. For example, it is contemplated that other metals may be utilized to form either the front surface contact 204 or the back surface contact 206, including gold, silver, aluminum, platinum, or combinations thereof. In another embodiment, it is contemplated that the silicon nitride layer 210b may be eliminated. In such an embodiment, the aluminum oxide layer 210a may have a thickness of about 100 nm. In yet another embodiment, it is contemplated that the diameter and pitch of the contact openings 212 may be varied to provide the desired level of electrical connection by increasing the contact area between the substrate 202 and the back contact 106. Additionally, the distance 216 can be reduced by increasing the contact area between the substrate 202 and the back surface contact 206 (e.g., the diameter of the local contacts 214).

FIG. 3 is a schematic plan view of a back surface (e.g., non-light-receiving surface) of the solar cell 200 shown in FIG. 2. The solar cell 200 includes a back surface contact 206 which may include of a plurality of busbars 318 and a plurality of fingers 320 in electrical communication therewith. A plurality of contact openings 212 (shown in phantom) are disposed through the passivation layer 210 and beneath the back surface contact 206 to facilitate electrical connection between the back surface contact 206 and the substrate 202 of the solar cell 200. It is contemplated that the size and pitch of the contact openings 112, as well as the number and spacing of the busbars 318 and the fingers 320 may vary to provide the desired electric current flow. The back surface contact 206 may have a thickness within a range of about 5 microns to about 50 microns. In one example, to reduce the manufacturing cost of the solar cell, the back surface contact 206 is configured to cover about 50% or less of the surface area of the non-light-receiving side of the solar cell 200. The back surface contact 206 generally has a sheet resistance within a range of about 5 milliohms-per-square to about 50 milliohms-per square and a contact resistivity within a range of about 1 milliohms-centimeter² to about 100 milliohms-centimeter² (mΩ-cm²).

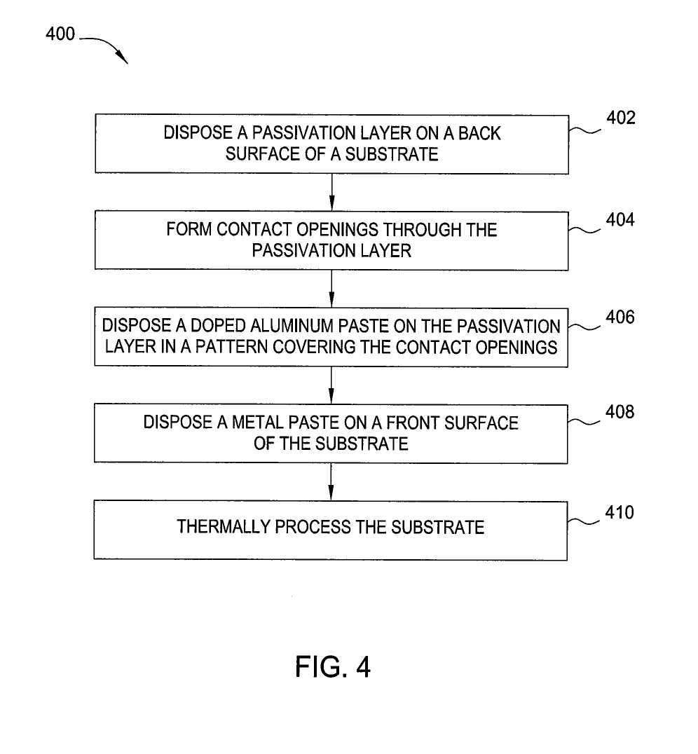

FIG. 4 is a flow diagram 400 illustrating a process sequence of forming the solar cell according to the embodiment shown in FIGS. 2 and 3. It is noted that the processing sequences depicted in FIG. 4 are only used as an example of a process flow that can be used to manufacture a solar cell device. Some steps may be added or eliminated as needed to form a desirable solar cell device.

The flow diagram 400 begins at box 402, in which a passivation layer is disposed on the back surface (i.e., non-light receiving side) of a substrate, such as a p-type crystalline silicon (c-Si) substrate. The passivation layer may include two sub-layers, such as a first sub-layer of aluminum oxide and a second sub-layer of silicon nitride on the first sub-layer. In one example, the two sub-layers are each deposited via plasma-enhanced chemical vapor deposition (PECVD), and may be deposited in the same or separate processing chambers without breaking vacuum. In another example, one or more of the two sub-layers are deposited using a physical vapor deposition (PVD) or an atomic layer deposition (ALD) process. The first sub-layer of aluminum oxide generally has a thickness of about 20 nm or more, for example, about 50 nm. The first sub-layer of aluminum oxide may be formed by reacting an aluminum-containing precursor, such as aluminum acetylacetonate or trimethyl aluminum (TMA) with an oxygen containing precursor such as diatomic oxygen (O₂), ozone (O₃) or nitrous oxide (N₂O). The second sub-layer of silicon nitride generally has a thickness within a range of about 20 nm to about 200 nm, such as about 50 nm to about 80 nm. The second sub-layer of silicon nitride may be formed by reacting a silicon-containing precursor, such as silane (SiH₄), with a nitrogen containing precursor, such as ammonia (NH₃) or nitrogen (N₂).

At box 404, after the passivation layer is formed on the back surface of the substrate, a laser patterning process may be performed to form a plurality of contact openings through at least a portion of the passivation layer to expose the back surface of the substrate. The plurality of contact openings are formed through the passivation layer to enable an electrical connection between the substrate and a subsequently deposited back surface contact utilized for current extraction.

In one embodiment, the laser patterning process is performed by delivering one or more laser pulses to portions of the passivation layer to form a desired pattern of contact openings through the second sub-layer of silicon nitride and the first sub-layer of aluminum oxide, such as local contact openings 212 shown in FIG. 3. The laser may be a diode-pumped solid-state laser and have a wavelength between about 180 nm and about 1064 nm, such as about 355 nm. In one example, a 200 kHz Q-switch frequency laser may deliver four laser pulses at 355 nanometers and 2.7 watts of energy to form the contact openings to the desired depth and size. Each pulse is focused or imaged to spots at certain regions of the passivation layer to form contact openings therethrough. Each contact opening within the passivation layer may be spaced at an equal distance to each other. Alternatively, each contact opening may be configured to have different distances to one another.

In one embodiment, the spot size of the laser pulse is controlled at between about 5 μm and about 100 μm, such as about 25 μm. The spot size of the laser pulse may be configured in a manner to form spots in the passivation layer with desired dimensions and geometries. In one embodiment, a spot size of a laser pulse may be about 25 μm in diameter to form a contact opening in the passivation layer with a diameter ranging between about 20 μm to about 200 μm, and a pitch (e.g., contact spacing between centers of contact openings) of about 100 μm to about 1000 μm. In one example, the contact openings may cover about 2% to about 5% of the non-light-receiving surface of the substrate.

The laser pulse may have energy density (e.g., fluence) between about 1 Joule per square centimeter (J/cm²) and about 100 Joules per square centimeter (mJ/cm²). Each laser pulse length may be configured to be about 80 nanoseconds in length. The laser pulse is continuously pulsed until the contact openings are formed in the passivation layer exposing the underlying substrate. In one embodiment, the laser may be continuously pulsed for between about 1 picosecond and about 80 nanoseconds, such as about 50 nanoseconds, at 532 wavelength 16 W, and 65 micro-Joules per square centimeter delivered to a work surface. After a first contact opening, for example, is formed in a first position defined in the passivation layer, a second contact opening is then formed by moving the laser pulse to a second location where the second contact opening is desired to be formed in the passivation layer. The laser patterning process is continue until a desired number of the contact openings are formed in the passivation layer.

At box 406, a paste, such as an aluminum paste doped with a metal or non-metal element, is selectively deposited on the passivation layer in a pattern covering the contact openings to form back surface contacts. The paste may be deposited by ink jet printing, rubber stamping, stencil printing, screen printing, or other similar process to form and define a desired pattern (e.g., grid like pattern shown in FIG. 3) where contact openings to the underlying substrate surface are formed. In one embodiment, the paste is disposed in a desirable pattern on the substrate 102 by a screen printing process in which the back contact metal paste is printed on the passivation layer through a stainless steel screen. In one example, the screen printing process may be performed in a SoftLine™ system available from Applied Materials Italia S.r.l., which is a division of Applied Materials Inc. of Santa Clara, Calif. It is also contemplated that deposition equipment from other manufactures may also be utilized.

In one embodiment, the paste is an alloy comprising aluminum and a doping element selected from the Group III elements such as boron, gallium, or indium. Other elements, such as silicon, antimony, magnesium, or the like, may be additionally used. In one example, the paste is a boron-doped aluminum paste. In such an example, the paste may include about 70 wt % to about 99.9 wt % aluminum and about 0.1 wt % to about 10 wt % boron, for example, about 0.5 wt % to about 1 wt % boron. The boron source may be boron metal powder, an alloy of boron, a salt of boron, boric acid, organometallic boron, an oxide of boron, boron-containing glass, or a combination of any of the foregoing. The boron may alternatively be doped in the Al powder. The boron-doped aluminum paste is used to form a heavily p+ doped back-surface field (BSF), such as the back-surface field (BSF) 213a shown in FIG. 2. The formed back-surface filed (BSF) 213a may have a thickness of about 1 micron to about 30 microns, for example about 15 microns, with an active doping concentration of about 10¹⁹ to about 10²⁰ atoms per cm³, which is about one or two orders of magnitude higher than is achievable with conventional Al paste.

It is desirable that the chosen paste suitably adheres to the underlying passivation layer. The pattern is generally a grid pattern including busbars and fingers perpendicular thereto. However, other patterns are also contemplated. The grid pattern of the back surface contact reduces the amount of aluminum required to form the back surface contact, particularly when compared to flood-printed back surface contacts, which cover the entire back surface of the solar cell. The reduction in aluminum usage, for example, 50% to about 70%, reduces the cost-per-watt generated because the cost of manufacturing the solar cell is reduced.

At box 408, a silver paste is disposed on the light-receiving surface of the solar cell to form a front surface contact grid. The front surface contact grid may have a shape or pattern similar to the back surface contact, and may be deposited by any suitable technique such as a screen printing process.

At box 410, the substrate, having the as-described pastes (i.e., the pastes for the front and back surface contacts) disposed thereon, is processed by a thermal processing step—a thermal metallization process known as a co-firing or “co-fire-through,” to simultaneously cause the pastes at the front and back surfaces or front and back contact grids to densify and form good electrical contacts with the various regions of the substrate all at once. The thermal metallization process, or co-firing process, will also cause at least a portion of the boron-doped aluminum paste to form reliable and heavily p⁺ doped back-surface-field (BSF) in the underlying substrate, as shown in FIG. 2. Thermal processing of the substrate may include heating the substrate to a temperature above the eutectic temperature of the materials of the substrate and the back surface contact (e.g., silicon and aluminum). Thereafter, the substrate is cooled. In one embodiment where a silicon substrate having a boron-doped aluminum paste deposited thereon is used, the co-firing process comprises heating the substrates to a peak firing temperature of between about 600° C. and about 900° C., such as about 850° C. for a short time period, such as between about 5 seconds and about 25 seconds, for example, about 10 seconds. The maximum temperature reached during thermal processing, as well as the length of time the substrate is thermally processed, influences the boron and aluminum concentrations in the local back contacts, as well as the depth of the back-surface field in the substrate.

During the heating ramp of the co-firing process, aluminum and boron within the boron-doped aluminum paste become fluid and migrate towards the substrate through the formed contact openings. Simultaneously, silicon from the substrate becomes fluid and diffuses outwards through the contact openings towards the back surface contact. During the cooling ramp of the co-firing process, the dissolved silicon diffuses back to the substrate and is re-grown on the silicon substrate surface by alloying with the aluminum and boron. Particularly, the boron dopes the re-grown silicon more heavily than aluminum due to the higher solid solubility of boron in silicon or silicon liquid alloy compared to aluminum, thereby forming a heavily boron-doped region (e.g., back-surface field (BSF) 213a shown in FIG. 2) within the contact openings. At the end of the co-firing process, the diffused aluminum and the rest of the silicon (e.g., the dissolved silicon that is deeply spread in the melted boron-doped aluminum paste and unable to travel a long distance back to where it was dissolved) solidifies into a silicon-aluminum eutectic alloy in the region of the contact openings (e.g., eutectic region 213b shown in FIG. 2) near the formed back-surface field and local back contacts. The cooling ramp of the co-firing process may last about 1 minute to about 4 minutes, or longer to provide a longer diffusion time for the silicon to travel back and alloy with boron and aluminum, without forming voids within the contact openings. In one embodiment, the heating and cooling of the substrate may last about 1 minute to about 5 minutes. In another embodiment, the heating and cooling of the substrate may last about 40 seconds to about 90 seconds.

The formation of the eutectic alloy material within the contact openings reduces carrier recombination in the region of the contact openings due to the heavily boron doped junction formed in the substrate. The boron-doped aluminum paste in accordance with the present invention makes it possible to form a thinner (e.g., about 1-3 microns), heavily p⁺ doped back-surface field within each of the contact openings, which reduces the contact resistance of the back contact while avoiding a stress-induced bowing of the substrate due to the coefficient of thermal expansion mismatch between the substrate and the full-area Al alloyed BSF.

Flow diagram 400 generally describes one embodiment of the invention. However, additional embodiments are also contemplated. For example, it is contemplated that the silicon nitride layer of the passivation layer may be excluded. In such an embodiment, the aluminum oxide layer may be formed to a thickness of about 100 microns or more to allow for degradation of the aluminum oxide layer while still providing sufficient passivation qualities. In other embodiments, it is contemplated that a boron-doped silver-containing paste, rather than a boron-doped aluminum-containing paste, may be utilized to form the back contact. In such an embodiment, during thermal processing, the substrate and the boron-doped silver-containing paste thereon would be heated beyond the eutectic temperature for silver and silicon. For example, the substrate may be heated to a temperature within a range of about 900 degrees Celsius to about 1000 degrees Celsius. Additionally, due to the relatively greater conductivity of silver as compared to aluminum, the amount of silver utilized for the back contact may be reduced.

Methods of forming the heavily doped region in accordance with the present invention can be used for fabrication of other types of solar cell devices, such as back-contact solar cells. Back contact solar cells are advantageous compared to conventional silicon solar cells because back contact solar cells have a higher conversion efficiency due to reduced or eliminated contact obscuration losses (sunlight reflected from contact grid is unavailable to be converted into electricity). In addition, assembly of back contact cells into electrical circuits is easier because both conductivity type contacts are on the same surface. FIG. 5 depicts a perspective view of an emitter wrap through (EWT) solar cell 500, which is one type of back contact solar cell that may be benefit from the present invention. In general, the EWT cell wraps the current-collection junction (“emitter”) from the front surface to the back surface through doped conductive channels in the silicon substrate. Such conductive channels can be produced by, for example, forming holes in the silicon substrate with a laser and subsequently forming the emitter inside the holes at the same time as forming the emitter on the front and back surfaces. The unique feature of EWT cells, in comparison to conventional solar cells, is that there is no metal coverage on the front side (i.e., light-receiving surface) of the cell, which means that none of the light impinging on the cell is blocked, resulting in higher efficiencies.

The EWT solar cell 500 shown in FIG. 5 generally includes a silicon substrate 502. The silicon substrate may be p-type or n-type, and formed by a material similar to the substrate 202 as discussed above with respect to FIG. 2. Holes 510 utilized to form conductive vias are formed through the substrate 502, connecting the front surface 512 to the back surface 508 of the substrate 502. The holes 510 may be formed by laser drilling, dry etching, wet etching, or other suitable mechanical drilling technique. The diameter of the holes 510 may be from about 20 microns to about 150 microns, with a thickness of about 200 microns or less. The holes density per surface area is dependent, in part, on the acceptable total series resistance loss due to current transport in the emitter through the holes 510 to the back surface 508. The holes 510 are typically treated for high conductivity (e.g., by heavily diffused with an n-type dopant such as phosphorus) and to electrically isolate the holes 510 from the substrate 502. The holes 510 are connected on the back surface 508 to one of the current-collection gridlines, i.e., the negative-polarity gridline 504. That is, the negative-polarity gridline 504 is deposited in a pattern such that each row of holes 510 is covered by a line of the negative-polarity gridline 504. Other current-collection gridline with opposite polarity, i.e., the positive-polarity gridline 506, is connected to the substrate 502. The phosphorus diffusion on the wall of the holes 510 serves as an electrical conduction path between an n-type diffusion region on the front surface 512 and the negative-polarity gridline 504.

A paste formulated in accordance with the embodiment described above with respect to FIGS. 2-4 may be used to form the current-collection gridline, for example, the positive-polarity gridline 506, by screen-printing a boron-doped aluminum paste on the back surface 508 of the substrate 502. In one embodiment, the substrate 502 is subjected to a firing process at high temperatures, for example, a temperature above the eutectic temperature of silicon and aluminum, such as between about 600° C. and about 900° C., such as about 850° C. for a short time period, such as between about 5 seconds and about 25 seconds, for example, about 10 seconds. During the heating ramp of the firing process, aluminum and boron within the boron-doped aluminum paste become fluid and migrate towards the substrate 502. Simultaneously, silicon from the substrate 502 becomes fluid and diffuses towards the boron-doped aluminum paste. During the cooling ramp of the firing process, the dissolved silicon diffuses back to the substrate and re-grown on the silicon substrate surface by alloying with the aluminum and boron. Particularly, the boron dopes the re-grown silicon more heavily than aluminum due to the higher solid solubility of boron in silicon or silicon liquid alloy compared to aluminum, thereby forming a heavily boron-doped region in the back surface 508 of the substrate 502. After the p-type contact (i.e., heavily boron-doped region) is formed, a metal such as silver, may be deposited to cover the p-type contact to carry current to the cell edges. The heavily boron-doped region in the back surface 508 of the substrate 502 helps lower contact resistance and reduces recombination losses. While boron is described in this embodiment, it is contemplated that other p-type dopants, such as gallium or indium, may be used.

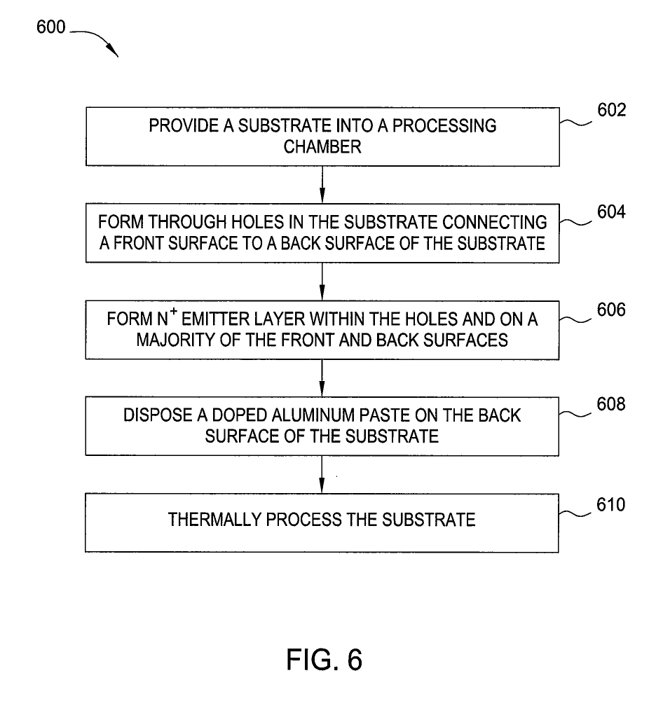

FIG. 6 depicts a flow diagram 600 illustrating a method of forming a solar cell of FIG. 5 according to one embodiment of the invention. It is noted that the processing sequences depicted in FIG. 6 are only used as an example of a process flow that can be used to manufacture an emitter wrap through (EWT) solar cell device. Some steps may be added or eliminated in between the steps depicted in FIG. 6 as needed to form a desirable solar cell device.

The flow diagram 600 begins at box 602 by providing a substrate, such as a p-type silicon substrate into a processing chamber. At box 604, the substrate is formed with a plurality of holes connecting the front surface to the back surface of the substrate. At box 606, an n⁺ emitter layer is formed within the holes and on a majority of the front surface and the back surface of the substrate. At box 608, a boron-doped aluminum paste is disposed on the back surface of the substrate, such as between the rows of the holes. At box 610, the substrate is thermally processed by heating the substrate to a temperature above the eutectic temperature of silicon and aluminum, thereby forming a heavily boron-doped region in the back surface of the substrate.

Benefits of the present invention include solar cells with increased efficiency and decreased cost. The increased efficiency and reduced cost is facilitated by a patterned back contact, which reduces the amount of paste required to manufacture a solar cell, and increases eutectic composition uniformity. Efficiency is further increased due to reduced contact resistance and reduction of recombination at the back surface of a solar cell which is facilitated by the heavily doped back surface field. Particularly, reduced contact resistance is promoted by using a boron-doped aluminum paste as the back surface contact. Heavily doped back surface field is achieved due to a higher solubility of boron in silicon than aluminum. Therefore, boron dopes the silicon more heavily than aluminum.

While the foregoing is directed to embodiments of the present invention, other and further embodiments of the invention may be devised without departing from the basic scope thereof, and the scope thereof is determined by the claims that follow.

What is claimed is:

1. A solar cell device, comprising:
a substrate;
a passivation layer disposed on a non-light-receiving surface of the substrate, the passivation layer having a plurality of openings formed therethrough, the passivation layer comprising:
a first sub-layer of aluminum oxide; and
a second sub-layer of silicon nitride disposed on the first sub-layer of aluminum oxide;
a back contact disposed on the passivation layer in a grid-like pattern covering the openings, the back contact comprising aluminum doped with a Group III element; and
a plurality of local contacts formed at an interface of the substrate and the back contact disposed within the openings, the plurality of local contacts comprising a region heavily doped with the Group III element and a silicon-aluminum eutectic alloy formed adjacent to the heavily doped region.

2. The solar cell device of claim 1, wherein the region has an active doping concentration of about 10¹⁹ to about 10²⁰ atoms per cm³.

3. The solar cell device of claim 1, wherein the openings have a pitch within a range of about 100 microns to about 1000 microns and a diameter within a range of about 20 microns to about 200 microns

4. The solar cell device of claim of claim 1, wherein the back contact comprises about 0.1 wt % to about 10 wt % of boron, gallium or indium.

5. The solar cell device of claim 1, wherein the back contact covers about 50% or less of the non-light-receiving surface.

6. The solar cell device of claim 1, wherein the first sub-layer of aluminum oxide has a thickness of about 20 nm or more, and the second sub-layer of silicon nitride has a thickness of about 20 nm to about 100 nm.

7. The solar cell device of claim 1, wherein the region heavily doped with the Group III element has a thickness of about 1 micron to about 5 microns.

8. A method of forming a solar cell, comprising:
disposing a passivation layer on a non-light receiving surface of a substrate, the passivation layer comprising:
a first sub-layer of aluminum oxide; and
a second sub-layer of silicon nitride disposed on the first sub-layer of aluminum oxide;
forming a plurality of openings through the passivation layer;
disposing an aluminum paste over the passivation layer in a grid-like pattern covering the openings, wherein the aluminum paste comprises a Group III element; and
heating the substrate and the aluminum paste disposed thereon to a temperature above a silicon-aluminum eutectic point.

9. The method of claim 8, further comprising:
after heating the substrate, cooling the substrate for about 1 minute to about 5 minute.

10. The method of claim 9, wherein heating and cooling the substrate forms a region heavily doped with the Group III element in the substrate.

11. The method of claim 9, wherein heating and cooling the substrate forms an aluminum-silicon eutectic composition within the openings of the passivation layer.

12. The method of claim 8, wherein the aluminum paste covers less than about 50% of the surface area of the non-light-receiving surface of the solar cell.

13. The method of claim 8, wherein the first sub-layer of aluminum oxide has a thickness of about 20 nm or more.

14. The method of claim 8, wherein the openings have a diameter of about 20 microns to about 200 microns, and a pitch of about 100 microns to about 1000 microns.

15. A method of forming a solar cell, comprising:
providing a substrate having a front surface and a back surface, the back surface is generally parallel and opposite to the front surface, the substrate having a first conductivity type;
forming a plurality of holes in the substrate, the holes extending from the front surface to back surface;
forming an emitter layer within the holes and on the front and back surfaces, the emitter layer having a second conductivity type opposite to the first conductivity type;
disposing an aluminum paste on the back surface of the substrate, the aluminum paste comprises a Group III element; and
heating the substrate and the aluminum paste disposed thereon to a temperature above a silicon-aluminum eutectic point to form a region heavily doped with the Group III element in the substrate.

16. The method of claim 15, wherein the front surface is electrically connected to the back surface via the plurality of holes.

17. The method of claim 15, wherein the plurality of holes has a diameter from about 20 microns to about 150 microns.

18. The method of claim 15, wherein the plurality of holes has a thickness of about 200 microns or less.

19. The method of claim 15, wherein the aluminum paste is doped with boron.

20. The method of claim 15, wherein the aluminum paste is disposed between the rows of the plurality of holes.
